(19) United States
(12) Patent Application Publication
(10) Pub. No.: US 2008/0112577 A1
(43) Pub. Date: May 15, 2008

(54) Automatic Volume Control of Audio Devices for Marine Vessels

(76) Inventor: Christian Crew, Betterton, MD (US)

Correspondence Address: Christian Crew, 17 6th Ave, Betterton, MD, 21610, US

(21) Appl. No.: 11/558,896

(22) Filed: Nov. 11, 2006

(51) Int. Cl. H03G 3/00

(52) U.S. Cl. 381/107

(57) ABSTRACT

This invention provides a means for automatically adjusting the volume of a marine audio device based upon the vessels engine(s) speed, or RPM. An engine speed, or RPM, input signal is processed such that the volume of the aforementioned device is increased or decreased as said signal changes. This is particularly useful when the volume of an audio device such as a radio or CD player, should be loud enough to hear when the vessel is under power but quiet enough for the user(s) to enjoy when the vessel is at rest.

### FIELD OF THE INVENTION

This invention provides a means for automatically adjusting volume of an audio device aboard a marine vessel, and more specifically, adjusting said volume based upon the engine(s) speed of the marine vessel.

### BACKGROUND OF THE INVENTION

In a pleasure boat or any other marine vessel, audio devices such as AM/FM receivers, CD, satellite, and mp3 players are commonly used. While a particular volume as the vessel is at rest is desirable, that same volume may not be adequate to hear while the vessel is under operation, and conversely a desired volume while the vessel is under power may be too great when the vessel is at rest. Compensation for this change in environmental noise is currently done manually through the use of a single volume control usually located on the device.

### SUMMARY OF THE INVENTION

The invention provides a means for automatically adjusting volume of an audio device based upon an engine(s) speed signal. This signal may come from the distributor of a gasoline engine, the alternator or crank trigger, the engine tachometer itself, or any other means of detecting engine speed, or RPM (rotations per minute) as it is most commonly referred to as.

Although actual boat speed, in terms of miles per hour or knots, has been considered as another means of a signal source, it is not considered as practical for a few reasons. Most marine vessels use a mechanical speedometer that would further complicate integration of this invention to the vessel. Furthermore it is very common for these speedometers to malfunction that would cause a lack of speed signal to the said device rendering it useless. Therefore the best method for estimating vessel speed for this application would be to monitor engine RPM.

RPM signals are typically in the form of pulses for a gasoline system or a crank trigger setup whereas most diesel engines base this signal from the output voltage of the alternator. This signal would be used to determine an appropriate amount of gain from which to adjust the original volume set point.

### DESCRIPTION OF THE VIEWS WITHIN THE INVENTION DRAWING

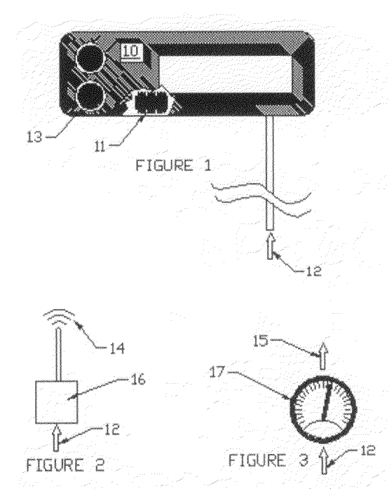

The drawing contained within illustrates the different parts of the system. A frontal view of the processing unit 10, as shown in FIG. 1, represents the component that would house circuitry 11, to process an RPM signal. This could be a standalone component or integrated into the audio device. FIG. 2 is representative of a wireless transmitter 16 where a signal indicative of RPM 12, would be converted into a wireless signal 14 and received by the processing unit. The view of FIG. 3 represents a tachometer 17 that would generate a signal 13 that would be read as an RPM signal by the processing unit 10.

What is claimed;

1. A means for automatically controlling volume of a marine vessel audio device 10 (FIG. 1) consisting of;
a. a signal representative of vessels engine(s) RPM 12 (FIGS. 1, 2, and 3)
b. electronic circuitry that processes said signal 11 (FIG. 1) so that the gain of a volume setting is automatically adjusted as said signal changes.

2. The method defined in claim 1 additionally comprising of a manual adjustment 13 (FIG. 1 ) to decrease or increase the effect of the gain thereby allowing changes in engine(s) speed to have a little or substantial effect on the volume output of the device.

3. The method defined in claim 1 whereas the engine(s) speed signal is generated or obtained from a tachometer 17 (FIG. 3).

4. The method defined in claim 1 whereas the signal representative of the engine(s) speed is transmitted wirelessly 14 (FIG. 2) via a transmitting device 16 (FIG. 2).
